(19) United States
(12) Patent Application Publication
(10) Pub. No.: US 2017/0263793 A1
(43) Pub. Date: Sep. 14, 2017

(54) PHOTODETECTOR AND OBJECT DETECTION SYSTEM USING THE SAME

(71) Applicant: KABUSHIKI KAISHA TOSHIBA, Minato-ku (JP)

(72) Inventors: Risako UENO, Meguro (JP); Kazuhiro SUZUKI, Minato (JP); Hiroto HONDA, Yokohama (JP); Koichi ISHll, Kawasaki (JP); Hideyuki FUNAKI, Shinagawa (JP)

(73) Assignee: KABUSHIKI KAISHA TOSHIBA, Minato-ku (JP)

(21) Appl. No.: 15/385,139

(22) Filed: Dec. 20, 2016

(30) Foreign Application Priority Data
Mar. 10, 2016 (JP) 2016-047009

(51) Int. Cl. H01L 31/0232; H01L 31/028; H01L 31/0216; G01S 17/10; H01L 31/0224; H01L 31/02; G01S 7/481; G01S 7/486; H01L 27/144; H01L 31/107

(52) U.S. Cl. CPC H01L 31/02327; H01L 27/1446; H01L 31/028; H01L 31/02161; H01L 31/107; H01L 31/022408; H01L 31/02027; G01S 7/4818; G01S 7/4861; G01S 7/4865; G01S 17/10

(57) ABSTRACT

A photodetector according to an embodiment includes: a semiconductor substrate including a first region and a second region adjacent to the first region; at least one light detection cell including a first semiconductor layer disposed in the first region, a second semiconductor layer disposed between the first semiconductor layer and the semiconductor substrate and including a junction portion with the first semiconductor layer, a third semiconductor layer disposed in the semiconductor substrate separately from the second semiconductor layer, a first electrode on the semiconductor substrate and applying a voltage to the first semiconductor layer, and a second electrode on the semiconductor substrate and applying a voltage to the third semiconductor layer; and a light guide disposed in the second region and guiding incident light to be propagated in a first direction to the junction portion between the first semiconductor layer and the second semiconductor layer.

### CROSS REFERENCE TO RELATED APPLICATIONS

This application is based upon and claims the benefit of priority from prior Japanese Patent Application No. 2016-047009 filed on Mar. 10, 2016 in Japan, the entire contents of which are incorporated herein by reference.

### FIELD

Embodiments described herein relate generally to a photodetector and an object detection system using the photodetector.

### BACKGROUND

Photodetectors with a quantum well structure including a compound semiconductor such as InGaAs or a chalcopyrite type semiconductor to have a high sensitivity to near-infrared light are known. However, the photodetectors including a compound semiconductor are more difficult to manufacture and more expensive than silicon-based photodetectors, and are difficult to be mounted on a substrate together with CMOS circuits.

The silicon-based photodetectors may be manufactured in large quantities at a low cost, and may be easily formed at the same time as CMOS circuits used for a read operation. However, the light absorption efficiency in the near-infrared region of the silicon-based photodetectors is lower than that of compound semiconductor-based photodetectors. As means to improve the sensitivity to light in the near-infrared region, a technique in which the thickness of a depletion layer associated with a light-absorption optical path length is increased and a technique in which protrusions and depressions are irregularly disposed at least in a region facing a pn junction in a silicon substrate, are known.

However, if the thickness of a depletion layer is increased, the drive voltage needs to be increased as well. This makes it difficult to produce minute photodetector arrays. Furthermore, a dedicated processing machine is needed to make irregularities on a silicon substrate. Thus, it has been difficult to improve the sensitivity to light in the near-infrared region with a simple structure.

### BRIEF DESCRIPTION OF THE DRAWINGS

FIG. 1 is a perspective view of a photodetector according to a first embodiment.

FIGS. 2A to 2C are diagrams showing light rays horizontally propagating in a light guide with a taper angle.

FIG. 3 is a diagram showing the dependency of light entering a light guide on the taper angle.

FIGS. 4A and 4B are diagrams showing the sensitivity of an APD cell having an aperture ratio of 64% to near-infrared light when the near-infrared light perpendicularly enters a substrate.

FIGS. 5A and 5B are diagrams showing the sensitivity of an APD cell having an aperture ratio of 64% with respect to near-infrared light when the near-infrared light horizontally enters a substrate.

FIG. 6 is a cross-sectional view of a photodetector according to a second embodiment.

FIG. 7 is a block diagram of a long distance object detection system according to a third embodiment.

### DETAILED DESCRIPTION

A photodetector according to an embodiment includes: a semiconductor substrate of a first conductivity type including a first region and a second region that is adjacent to the first region; at least one light detection cell including a first semiconductor layer of a second conductivity type disposed in the first region, a second semiconductor layer of the first conductivity type disposed between the first semiconductor layer and the semiconductor substrate and including a junction portion with the first semiconductor layer, a third semiconductor layer of the first conductivity disposed in the semiconductor substrate separately from the second semiconductor layer, a first electrode on the semiconductor substrate and configured to apply a voltage to the first semiconductor layer, and a second electrode on the semiconductor substrate and configured to apply a voltage to the third semiconductor layer; and a light guide disposed in the second region and configured to guide incident light to be propagated in a first direction, which is parallel to a surface of the semiconductor substrate, to the junction portion between the first semiconductor layer and the second semiconductor layer.

Embodiments will now be described with reference to the accompanying drawings.

### First Embodiment

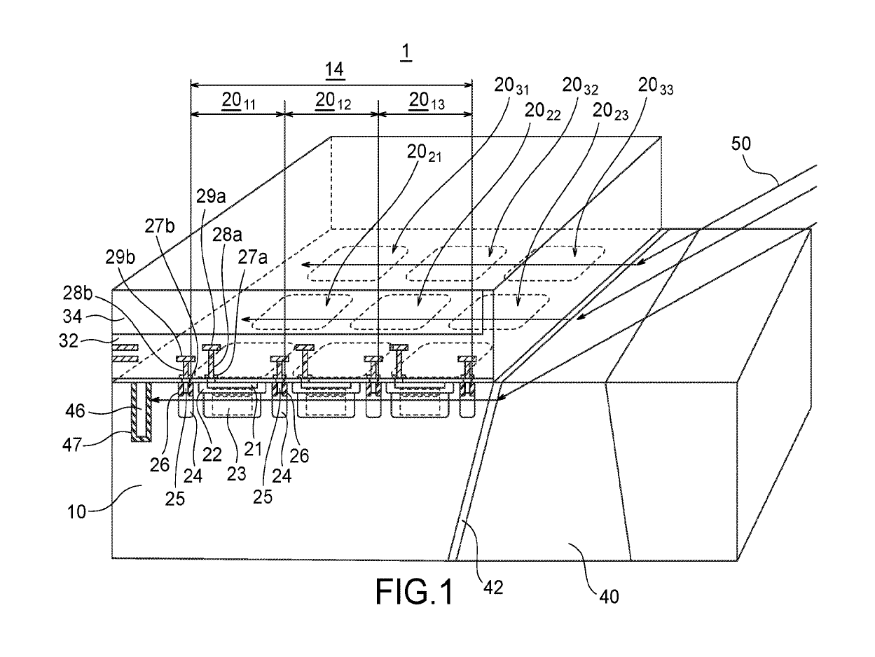

FIG. 1 shows a photodetector according to a first embodiment. The photodetector 1 includes a semiconductor substrate (for example, a p⁻-type silicon substrate) 10, a plurality of light detection cells 20₁₁ to 20₃₃ arranged in a matrix form on the semiconductor substrate 10, a light guide 40, and an antireflection film 42. The light detection cells 20₁₁ to 20₃₃ are disposed in a cell array region 14 of the semiconductor substrate 10.

Each light detection cell 20ᵢⱼ (i, j=1, 2, 3) is a photodiode, including an n⁺-type semiconductor layer 21 disposed in the surface, a p-type semiconductor layer 23, an n-type semiconductor layer 22 disposed between the n⁺-type semiconductor layer 21 and the p-type semiconductor layer 23 and having a lower n-type impurity concentration than the n⁺-type semiconductor layer 21, a p-type semiconductor layer 24 disposed in the semiconductor substrate 10 separately from the p-type semiconductor layer 23, a p⁺-type semiconductor layer 25 disposed in the surface of the semiconductor substrate 10, connected to the p-type semiconductor layer 24, and having a higher p-type impurity concentration than the p-type semiconductor layer 24, a first electrode 27a connecting to the n⁺-type semiconductor layer 21, and a second electrode 27b connecting to the p⁺-type semiconductor layer 25. Additionally the second electrode 27b is disposed to each light detection cell row. For example, four second electrodes 27b are provided to the light detection cells 20₁₁, 20₁₂, and 20₁₃. The second electrode 27b is disposed on the left side of each of the light detection cells 20₁₁, 20₂₁ and 20₃₁ in FIG. 1. This makes each light detection cell in the same row, for example, each of the light detection cells 20₁₁, 20₁₂, and 20₁₃, sandwiched between two second electrodes 27b. Device isolation insulating layer 26 of, for example, SiO₂ or SiN is disposed on sides of each p⁻-type semiconductor layer 25. The device isolation insulating layer 26 also surrounds the n-type semiconductor layer 22 of each light detection cell 20ᵢⱼ (i, j=1, 2, 3). Thus, each light detection cell 20ᵢⱼ (i, j=1, 2, 3) is isolated by the device isolation insulating layer 26.

An interlayer insulating layer 32 is disposed on the light detection cells 20₁₁ to 20₃₃, and an interlayer insulating layer 34 is disposed on the interlayer insulating layer 32. Wiring lines 29 connecting to the first electrodes 27a and wiring lines 29b connecting to the second electrodes 27b are disposed in the interlayer insulating layer 32. Contacts 28a each connecting one of the first electrodes 27a to one of the wiring lines 29a, and contacts 28b each connecting one of the second electrodes 27b to one of the wiring lines 29b are also disposed in the interlayer insulating layer 32.

The light guide 40 is disposed in the semiconductor substrate 10 adjacent to the cell array region 14, and guides light rays 50 incident on the photodetector 1 to the light detection cells 20₁₁ to 20₃₃. The light guide 40 has an inverted taper structure, by which the cross section in a plane parallel to the surface of the semiconductor substrate 10 is broadened from the upper face to the lower face of the semiconductor substrate 10. The inverted taper structure allows the light rays 50 that obliquely enter the semiconductor substrate from above to horizontally be propagated in the semiconductor substrate. The light guide 40 may be an air layer, or formed of a material that is transparent to the incident light rays 50, such as SiO₂. If the light guide 40 is an air layer, it is an opening.

An antireflection layer 42 for preventing reflection of the incident light rays 50 is disposed between the face from which the light rays 50 enter the semiconductor substrate 10 and the semiconductor substrate 10, i.e., between the light guide 40 and the semiconductor substrate 10. The antireflection layer 42 may be formed of, for example, SiO₂ or SiN.

A reflection region 46 of a metal with high reflectivity is disposed at an end of the cell array region 14 opposite to the light guide 40. The reflection region 46 is covered by an insulating layer 47, reflects light rays passing through the light detection cells 20₁₁ to 20₃₃ via the light guide 40 and the semiconductor substrate 10, and causes the reflected light rays to enter the light detection cells 20₁₁ to 20₃₃ again. The reflection region 46 may be omitted.

The operation of the photodetector 1 according to the first embodiment will be described below. First, a positive voltage is applied to the first electrode 27a, and a negative voltage is applied to the second electrode 27b of each light detection cell. As a result, a depletion layer (a region surrounded by a broken line) is formed in the p-type semiconductor layer 23. If one photon enters the depletion layer of any light detection cell 20ᵢⱼ (i, j=1, 2, 3) via the light guide 40, one electron and one hole that make a pair are generated in the depletion layer. The generated electron is multiplied at the junction portion between the p-type semiconductor layer 23 and the n-type semiconductor layer 22, and flows to the first electrode 27a via the n⁺-type semiconductor layer 21. The electron flowing to the first electrode 27a is sent to a readout circuit (not shown) via the contact 28a and the wiring line 29a. The hole generated in the depletion layer flows from the p-type semiconductor layer 23 to the second electrode 27b through the semiconductor substrate 10, the p-type semiconductor layer 24, and the p⁺-type semiconductor layer 25. The hole flowing to the second electrode 27b is sent to a readout circuit (not shown) via the contact 28b and the wiring line 29b.

As a result, a current corresponding to the photon entering the light detection cell 20ᵢⱼ flows between the first electrode 27a and the second electrode 27b. The number of photons entering the light detection cell may be detected by reading the current by the readout circuit (not shown). The number of photons entering the photodetector 1 may be detected by connecting the light detection cells 20₁₁ to 20₃₃ in parallel, and reading the sum of current values flowing through the light detection cells 20₁₁ to 20₃₃ by the readout circuit (not shown). Alternatively, each light detection cell may be separately connected to the readout circuit.

In the first embodiment, the conductivity type of each of the semiconductor layers and the semiconductor substrate 10 may be reversed. For example, the n⁺-type semiconductor layer 21 may be a p⁺-type semiconductor layer, the n-type semiconductor layer 22 may be a p-type semiconductor layer, the p-type semiconductor layer 23 may be an n-type semiconductor layer, the p-type semiconductor layer 24 may be an n-type semiconductor layer, the p⁺-type semiconductor layer 25 may be an n⁺-type semiconductor layer, and the p⁻type semiconductor substrate 10 may be an n⁻-type semiconductor substrate. In this case, the polarity of the voltage applied to each of the first electrode 27a and the second electrode 27b is also reversed.

### (Taper Angle of Light Guide)

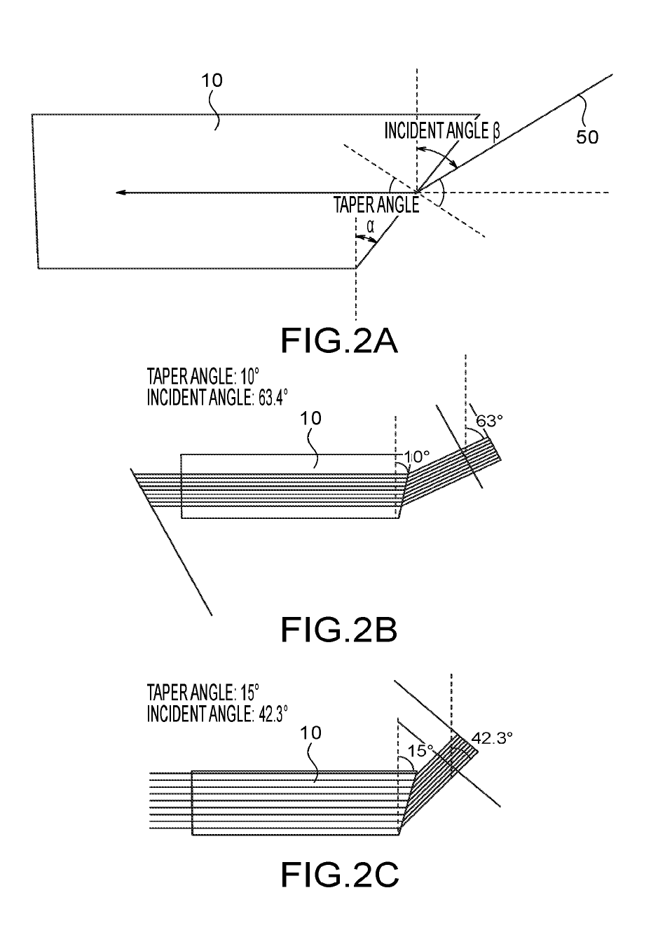

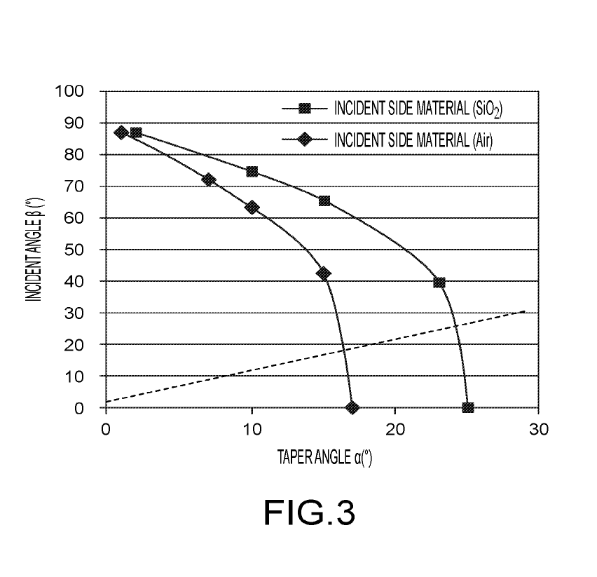

The taper angle of the light guide 40 will be described with reference to FIGS. 2A to 3. If the light guide 40 has a taper angle α°, the semiconductor substrate 10 has also the same taper angle α°. In FIG. 2A, incident light rays 50 enter, with an incident angle β, a taper face of the semiconductor substrate 10 tapered at a taper angle α°. According to a calculation, if the semiconductor substrate 10 is formed of silicon and has a taper angle α of 10°, the incident angle β of the light rays 50 needs to be 63.4° in order for the light rays 50 to horizontally propagate in the semiconductor substrate 10. FIG. 2B shows this state. According to another calculation, if the semiconductor substrate 10 is formed of silicon and has a taper angle α of 15°, the incident angle β of the light rays 50 needs to be 42.3° in order for the light rays 50 to horizontally propagate in the semiconductor substrate 10. FIG. 2C shows this state. In the calculations of the incident angle of the light rays 50 shown in FIGS. 2B and 2C, the refractive index of silicon is assumed to be 3.42, and the refractive index of air is assumed to be 1.0.

FIG. 3 shows the dependency of the incident angle β on the taper angle α if light rays need to horizontally propagate in the semiconductor substrate 10 when the material in contact with the incident face of the semiconductor substrate 10 of silicon is SiO₂, and is air. FIG. 3 shows that as the taper angle α increases, the incident angle β decreases. If the semiconductor substrate 10 is formed of silicon and the material of the light guide 40 is air, a maximum taper angle α is 17°. Thus, the taper angle a of the light guide 40 is preferably more than 0°, and 17° or less.

### (Light Detection Cell)

In the first embodiment, each light detection cell 20ᵢⱼ (i, j=1, 2, 3) may be, for example, an avalanche photodiode (“APD”) containing a silicon material.

An APD is a photo-sensing element to which a reverse-bias voltage that is higher than the reverse breakdown voltage is applied in a stand-by state. This allows the APD to operate in a region called “Geiger mode.” The gain of the APD operating in the Geiger mode is very high, 10⁵ to 10⁶. Therefore, subtle light such as a single photon may be measured by the APD.

Generally, a resistor having a high resistance value called “quench resistor” is connected in series to each APD. When a single photon enters an APD and a Geiger discharge is caused, the multiplication effect is terminated by the voltage drop caused by the quenching resistor. Therefore, a pulse-shaped output signal is obtained.

In a silicon photomultiplier (“SiPM”), in which APDs are connected in parallel, each APD operates in this manner. Therefore, if the Geiger discharge is caused in two or more APDs, an output signal with an electric charge value or pulse wave height value that is a value of an output signal of one APD times the number of APDs in which the Geiger discharge occurs may be obtained. Therefore, the number of APDs in which the Geiger discharge occurs, i.e., the number of photons entering the SiPM, may be measured from the output signal. This allows single photon counting to be performed.

A light detection cell using an APD as a photo-sensing element is driven with a reverse-bias voltage that is higher than the breakdown voltage. The depletion layer of the APD generally has a thickness of 2 μm to 3 μm, and a reverse-bias voltage applied thereto is generally 100 V or less. In order to improve the near-infrared light sensitivity in a silicon photodiode, the thickness of the depletion layer (sensitive region) needs to be increased. However, increasing the thickness causes problems such as an increase in drive voltage and/or chip size, and a delay in response speed. Therefore, improving the sensitivity by elongating the length of the sensitive region (optical path length), through which light rays pass, without causing the drive voltage to increase may be effective.

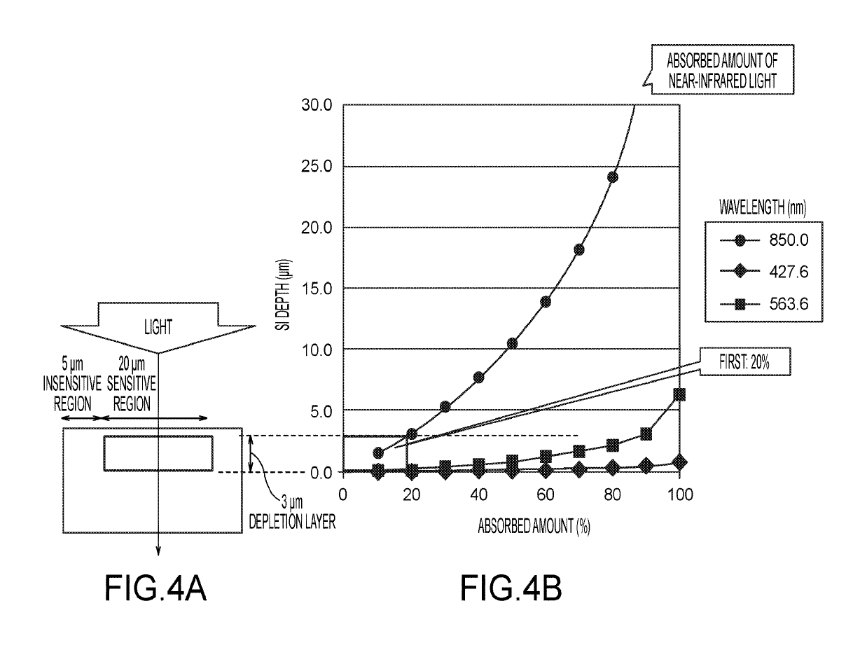

FIG. 4A shows a cross section of an APD in which a sensitive region has a length of 20 μm, an insensitive region has a length of 5 μm, and a depletion layer has a depth of 3 μm. FIG. 4B shows a result of a calculation for obtaining an absorbed amount of near-infrared light (wavelength 850 nm) when the near-infrared light perpendicularly enters the substrate. FIG. 4B also shows the calculation results for obtaining absorbed amounts of light having wavelengths of 427.6 nm and 563.6 nm. The absorbed amounts are calculated based on the light absorption characteristic of silicon. The APD shown in FIG. 4A is a photo-sensing element with two dimensional aperture ratio of 64%. Since the light perpendicularly enters the surface of the substrate, only one photo-sensing element is capable of detecting the incident light. Since the absorption rate in the depth direction is 20% as shown in FIG. 4B, the photon conversion ratio in the near-infrared region is about 12% (=20%×64%).

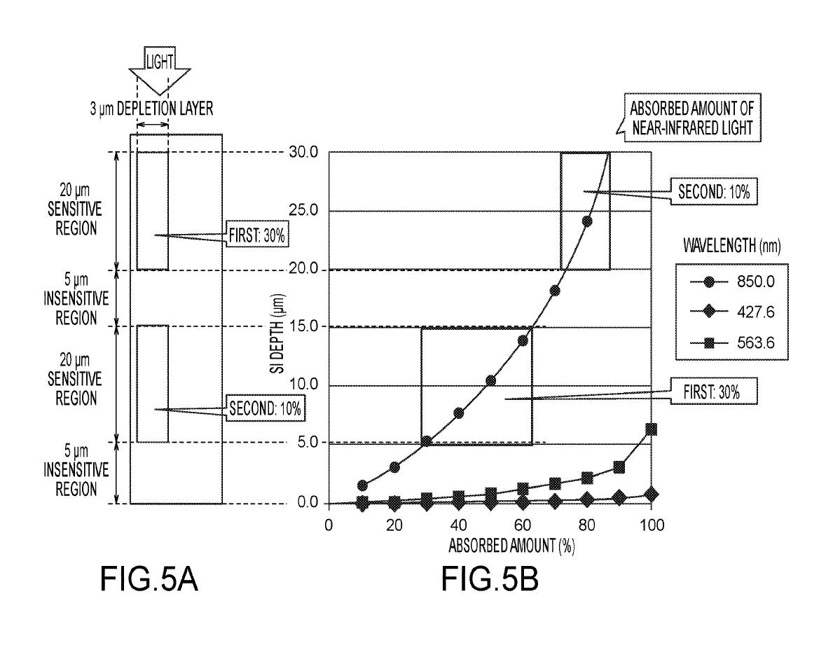

FIG. 5A is a schematic diagram showing that light horizontally enters a substrate of an APD with an aperture ratio of 64%, like the APD according to the first embodiment. The amount of absorbed near-infrared light (wavelength 850 nm) in the APD shown in FIG. 5A is calculated. FIG. 5B shows the result. FIG. 5B also shows the calculation results with respect to the light having the wavelengths of 427.6 nm and 563.6 nm. The light entering the substrate along a horizontal direction, which is in parallel with the surface of the substrate, may pass through a plurality of APDs. Therefore, the amount of absorbed light may be increased. For example, two APDs having the aperture ratio of 64% may absorb 40% of incident light, as can be understood from FIG. 5B.

The photodetector 1 according to the first embodiment is capable of detecting light having a wavelength in a near-infrared region, from 750 nm to 1000 nm.

As described above, the photodetector according to the first embodiment is capable of improving the sensitivity to light in a near-infrared region with a simple structure.

### Second Embodiment

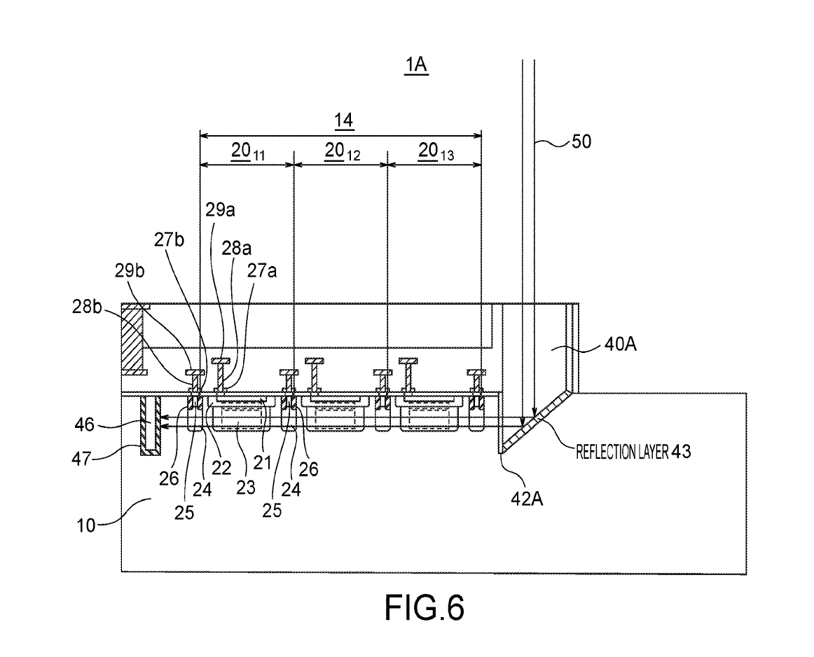

FIG. 6 shows a photodetector according to a second embodiment. The photodetector 1A according to the second embodiment has a structure in which the light guide 40 of the photodetector 1 according to the first embodiment shown in FIG. 1 is replaced with a light guide 40A.

The light guide 40A is disposed in the semiconductor substrate 10 adjacent to the cell array region 14, and is an opening that is perpendicular to the surface of the semiconductor substrate 10, or a transparent member fitted to such an opening, which is transparent to incident light. The bottom of the opening is slanted. A reflection layer 43 is disposed on the bottom. The slanted bottom of the opening causes light that perpendicularly enters the semiconductor substrate 10 and passes through the light guide 40A is reflected by the reflection layer 43 and passes through the p-type semiconductor layer 23 of the light detection cell in the cell array region 14 via an antireflection layer 42A. The antireflection layer 42A may be formed of SiO₂ or SiN.

The photodetector according to the second embodiment having the aforementioned simple structure is also capable of improving the sensitivity to light in a near-infrared region, like the first embodiment.

### Third Embodiment

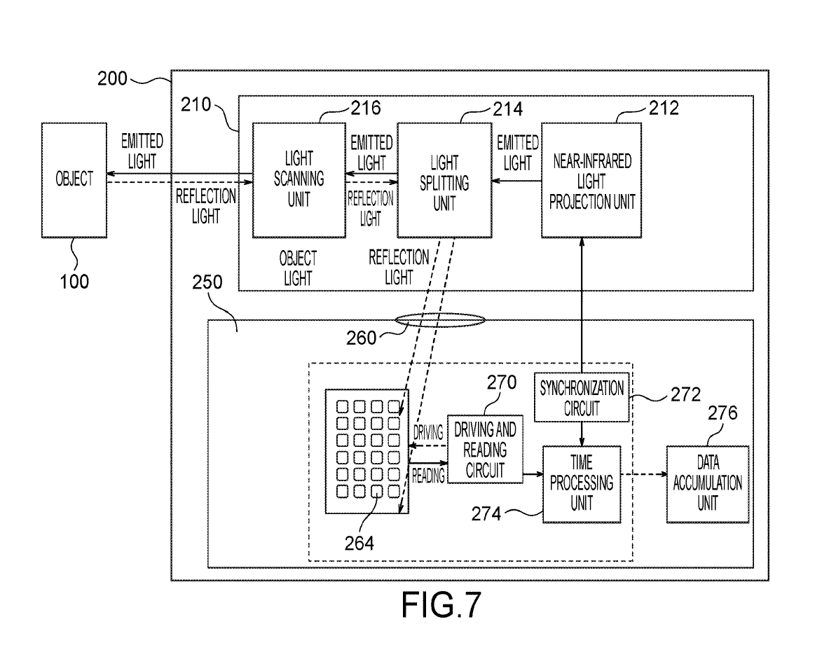

FIG. 7 shows an object detection system according to a third embodiment. The object detection system 200 according to the third embodiment includes a light projection unit 210 and a light detection unit 250. The light projection unit 210 emits light to an object 100. The light detection unit 250 detects reflection light reflected by the object 100 and returning through the same path as the emitted light, calculates the period of time during which the light returns to the emitted point (time of flight), the intensity of the returned light, etc. and estimates the distance to the object 100 based on the time of flight and the reflectivity of the object 100 based on the intensity.

The light projection unit 210 includes, for example, a near-infrared light projection unit 212 for emitting near-infrared light, a light splitting unit 214 including, for example, a beam splitter for splitting the emitted light and reflection light reflected from the object, and a light scanning unit 216 facing the object 100 and two-dimensionally scanning light in the horizontal direction and the vertical direction. The reflection light reflected from the object 100 and returning through the same path as the emitted light to the light scanning unit 216 is guided to the light detection unit 250 by the light splitting unit 214.

The light detection unit 250 includes a focusing lens 260 for focusing the light from the light splitting unit 214, a photodetector 264 for detecting the intensity of the light, a driving and reading circuit 270 for driving the photodetector 264 and reading the intensity of light from the photodetector 264, a synchronization circuit 272 for obtaining synchronization timing of the light emitted from the near-infrared light projection unit 212, a time processing unit 274 for calculating the period of time, during which the light emitted from the near-infrared light projection unit 212 returns, using the synchronization timing obtained from the synchronization circuit 272, and a data accumulation unit 276 for accumulating the two-dimensional data of the object 100 and the time data.

The third embodiment includes the photodetector 1 according to the first embodiment or the photodetector 1A according to the second embodiment as the photodetector 264 for detecting the near-infrared light reflected from the object 100. As a result, the object detection system 200 according to the third embodiment has an improved sensitivity to near-infrared light with a simple structure, like the first embodiment and the second embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A photodetector comprising:
a semiconductor substrate of a first conductivity type including a first region and a second region that is adjacent to the first region;
at least one light detection cell including a first semiconductor layer of a second conductivity type disposed in the first region, a second semiconductor layer of the first conductivity type disposed between the first semiconductor layer and the semiconductor substrate and including a junction portion with the first semiconductor layer, a third semiconductor layer of the first conductivity disposed in the semiconductor substrate separately from the second semiconductor layer, a first electrode on the semiconductor substrate and configured to apply a voltage to the first semiconductor layer, and a second electrode on the semiconductor substrate and configured to apply a voltage to the third semiconductor layer; and
a light guide disposed in the second region and configured to guide incident light to be propagated in a first direction, which is parallel to a surface of the semiconductor substrate, to the junction portion between the first semiconductor layer and the second semiconductor layer.

2. The photodetector according to claim 1, wherein the light guide is an opening that extends from the surface of the semiconductor substrate in a second direction that is perpendicular to the surface, or a transparent member fitted to the opening, the transparent member being transparent to the incident light, the opening having a side face at a boundary between the first region and the second region, the side face being slanted at a predefined angle to the second direction.

3. The photodetector according to claim 1, wherein the light guide is an opening that extends from the surface of the semiconductor substrate in a second direction that is perpendicular to the surface, the opening having a side face that is parallel to the second direction at a boundary between the first region and the second region, and a bottom that is slanted at a predefined angle to the second direction. 5

4. The photodetector according to claim 2, wherein the predefined angle is more than 0° and equal to or less than 17°.

5. The photodetector according to claim 2, wherein an antireflection layer is disposed on the side face.

6. The photodetector according to claim 1, further comprising a reflection region that reflects light in the first region, wherein the at least one light detection cell is disposed between the reflection region and the light guide.

7. The photodetector according to claim 1, wherein the at least one of the light detection cell is an avalanche photodiode.

8. The photodetector according to claim 1, wherein the at least one of the light detection cell detects near-infrared light having a wavelength in a range from 750 nm to 1000 nm.

9. The photodetector according to claim 1, wherein the at least one light detection cell is a plurality of light detection cells disposed along the first direction in the first region of the semiconductor substrate.

10. The photodetector according to claim 9, wherein the second electrode of one of two adjacent light detection cells of the plurality of light detection cells is disposed between the two adjacent light detection cells.

11. An object detection system comprising:
a light projection unit configured to emit light;
a light splitting unit configured to split the light and reflection light of the light, reflected from an object;
a light scanning unit facing the object and configured to scan the light emitted to the object;
a photodetector configured to detect the reflection light split by the light splitting unit, the photodetector being the photodetector according to claim 1;
a driving and reading circuit configured to drive the photodetector and read intensity of the reflection light sent from the photodetector;
a synchronization circuit configured to obtain synchronization timing of the light emitted from the light projection unit; and
a time processing unit configured to calculate, using the synchronization timing obtained by the synchronization circuit, a period of time during which the light emitted from the light projection unit returns.

12. The system according to claim 11, wherein the light guide is an opening that extends from the surface of the semiconductor substrate in a second direction that is perpendicular to the surface, or a transparent member fitted to the opening, the transparent member being transparent to the incident light, the opening having a side face at a boundary between the first region and the second region, the side face being slanted at a predefined angle to the second direction.

13. The system according to claim 11, wherein the light guide is an opening that extends from the surface of the semiconductor substrate in a second direction that is perpendicular to the surface, the opening having a side face that is parallel to the second direction at a boundary between the first region and the second region, and a bottom that is slanted at a predefined angle to the second direction.

14. The system according to claim 12, wherein the predefined angle is more than 0° and equal to or less than 17°.

15. The system according to claim 12, wherein an antireflection layer is disposed on the side face.

16. The system according to claim 11, further comprising a reflection region that reflects light in the first region, wherein the at least one light detection cell is disposed between the reflection region and the light guide.

17. The system according to claim 11, wherein the at least one of the light detection cell is an avalanche photodiode.

18. The system according to claim 11, wherein the at least one of the light detection cell detects near-infrared light having a wavelength in a range from 750 nm to 1000 nm.

19. The system according to claim 11, wherein the at least one light detection cell is a plurality of light detection cells disposed along the first direction in the first region of the semiconductor substrate.

20. The system according to claim 19, wherein the second electrode of one of two adjacent light detection cells of the plurality of light detection cells is disposed between the two adjacent light detection cells.
